(19) United States
(12) Patent Application Publication
(10) Pub. No.: US 2010/0118370 A1
(43) Pub. Date: May 13, 2010

(54) OSCILLATING BODY APPARATUS AND MANUFACTURING METHOD THEREOF, OPTICAL DEFLECTOR AND IMAGE FORMING APPARATUS

(75) Inventors: Kazunari Fujii, Kawasaki-shi (JP); Yoshio Hotta, Kamakura-shi (JP); Takahisa Kato, Tokyo (JP); Hiroyuki Morimoto, Tokyo (JP)

Correspondence Address: FITZPATRICK CELLA HARPER & SCINTO, 1290 Avenue of the Americas, NEW YORK, NY, 10104-3800, US

(73) Assignee: CANON KABUSHIKI KAISHA, Tokyo (JP)

(21) Appl. No.: 12/668,196

(22) PCT Filed: Aug. 20, 2008
(86) PCT No.: PCT/JP2008/065223

§ 371 Date: Jan. 7, 2010

(30) Foreign Application Priority Data
Aug. 30, 2007 (JP) 2007-223640
Mar. 18, 2008 (JP) 2008-069761

(51) Int. Cl. G02B 26/10; H01L 41/22

(52) U.S. Cl. 359/214.1; 29/25.35; 310/312

(57) ABSTRACT

An oscillating body apparatus comprises an oscillating plate oscillatably supported around a torsion axis by a support portion for a fixing portion and driving the oscillating plate around the torsion axis by a resonance frequency, the oscillating plate having a region forming a groove portion for adjusting a mass of the oscillating plate, and, the resonance frequency being configured to be adjustable by the formation of the groove portion in the region.

### TECHNICAL FIELD

The present invention relates to an oscillating body apparatus and the manufacturing method thereof, an optical deflector using the oscillating body apparatus, and an image forming apparatus.

For example, the invention relates to a technique capable of realizing an optical deflector using an oscillating body apparatus suitably applicable to an image forming apparatus such as a projection display for projecting an image by deflection scanning of light, a laser beam printer having an electrophotographic process and a digital copying machine.

### BACKGROUND ART

Up to now, a micromechanical member manufactured from a wafer by a semiconductor process has been processable in the order of micrometer, and by using these members, a variety of micromechanical elements have been realized.

For example, as an actuator (oscillating body apparatus) in which a movable element (oscillating plate) formed by such a technique is given torsional vibration and a resonance phenomenon of the movable element (oscillating plate) is utilized, various proposals have been put forward.

In particular, the optical reflector in which a reflection surface serving as the optical reflector is arranged on such a movable element (oscillating plate) and conducts optical scanning by utilizing the resonance phenomenon of the movable element (oscillating plate) has the following advantages as compared with an optical scanning optical system using a polygonal rotating mirror such as a conventional polygon mirror and the like.

That is, features are provided such that it is possible to miniaturize the optical reflector and that the optical reflector composed of a silicon single crystal manufactured by a semiconductor process has no metal fatigue in theory and is excellent in durability as well and that the consumption power is small, and the like.

Particularly, since the optical reflector is driven in the vicinity of the frequency of an intrinsic vibration mode of the torsional vibration of the movable element (vibrating plate), a low power consumption can be achieved.

However, on one hand, in the optical reflector utilizing such resonance phenomenon, due to size error and the like caused in the manufacturing process, variation in the resonance frequency which is the frequency of the intrinsic vibration mode between each actuator is generated.

Consequently, since such variation in the resonance frequency between each actuator is not preferable, there arises the necessity of adjusting the resonance frequency.

When using the actuator, in case a reference frequency which is an operation (drive) frequency is set to the predetermined value, the disagreement occurs between the frequency of the intrinsic vibration mode and the reference frequency.

Consequently, in the optical deflector comprised of such actuator, the disagreement with the frequency of the intrinsic vibration mode and the reference frequency causes variance in the swing angle of a movable element. In the electrophotographic process such as a laser beam printer using the optical reflector, the laser beam is scanned on a photosensitive member, thereby to form an image.

Consequently, to stabilize an aspect ratio of the image and suppress deterioration of the image, the necessity of adjusting the resonance frequency of the optical reflector to the predetermined value arises in order to eliminate variance in the swing angle of the movable element in the optical deflector when allowing the movable element to correspond to the rotating speed of the photosensitive member.

Heretofore, as an actuator capable of adjusting the resonance frequency as described above, Japanese Patent Application Laid-Open No. 2002-040355 has disclosed the following planar type galvano mirror.

In this technique, as illustrated in FIG. 9, the planer type galvano mirror is used, which is formed with mass load portions 1001 and 1002 at both ends of the movable plate having a reflection surface and a coil oscillatably elastically supported on a torsion axis 110.

By irradiating the mass load portions 1001 and 1002 with a laser beam of this galvano mirror, the mass is removed and an inertia moment is adjusted, thereby to set the frequency to the predetermined value.

Japanese Patent Application Laid-Open No. 2004-219889 discloses an oscillation mirror capable of coating a mass piece by resin on a mirror substrate (micro oscillating plate) and adjusting the resonance frequency.

As described above, in the actuator utilizing the resonance phenomenon, since it is desired to drive the movable element (vibrating plate) in the vicinity of the frequency of the intrinsic vibration mode when attempting at reducing the power consumption, the necessity of adjusting the resonance frequency arises.

Further, in the image forming apparatus using the optical deflector comprised of such an actuator, to stabilize an aspect ratio of an image and suppress deterioration of the image quality, the necessity of adjusting the resonance frequency of the optical reflector to the predetermined value arises.

However, in the conventional example described above, adjusting these resonance frequencies to the predetermined value causes the following problem.

In Japanese Patent Application Laid-Open No. 2002-040355, the coating of the mirror surface with resin increases an inertia moment, thereby to adjust the resonance frequency.

Further, the removal of the mass of a part of the mirror by the laser decreases the inertia moment, thereby to adjust the resonance frequency. In whichever case, when the resonance frequency is adjusted in a high precision, a position on which resin is coated is required to have high precision.

This is because, in the method of adjusting the resonance frequency by the removal of a part of the mirror by the resin or laser process as described above, there arises the following problem even when the processing position is slightly displaced (offset).

That is, when the mirror is oscillated in a state in which the resin (or the removal position) is offset with respect to an oscillating axis center, in case a resin mass (or a removal mass) is large, an inertia moment by the offset occurs, thereby sometimes to deteriorate an oscillating characteristic of the mirror.

Further, in Japanese Patent Application Laid-Open No. 2004-219889, by coating on the surface of the mirror with the axis of rotation as a target, the inertia moment is increased and the resonance frequency is adjusted.

In this case also similarly as described above, when the resonance frequency is adjusted with a high precision, the individual position coated with resin is required to have high precision.

As described above, in the conventional apparatus, an apparatus having high positioning accuracy is required, and this invites problems such as complication of the apparatus and lowering of a processing tact.

In view of the above described problems, an object of the present invention is to provide an oscillating body apparatus and the manufacturing method thereof capable of adjusting the mass of an oscillating plate with high precision at a lower cost by a simple configuration when adjusting the resonance frequency and an optical deflector and image forming apparatus using the oscillating body apparatus.

### DISCLOSURE OF THE INVENTION

The present invention provides an oscillating body apparatus and the manufacturing method thereof, an optical deflector using the oscillating body apparatus, and an image forming apparatus, which are configured as follows.

The oscillating body apparatus of the present invention is an oscillating body apparatus including an oscillating plate oscillatably supported by a support portion for a fixing portion and driving the oscillating plate around the torsion axis by the resonance frequency,

wherein the oscillating plate has a region forming a groove portion for adjusting a mass of the oscillating plate, and by the formation of the groove portion in the region, the resonance frequency of the oscillating body is configured to be adjustable. Further, the oscillating body apparatus of the present invention is wherein the oscillating plate includes a structure having the frequencies of at least two intrinsic vibration modes around the torsion axis by a first oscillating plate and a second oscillating plate, and wherein the groove portion is configured to be formable in a region that forms a groove portion in at least either one of the first oscillating plate and the second oscillating plate.

Further, the oscillating body apparatus of the present invention is wherein the oscillating plate includes an extended portion connected to the oscillating plate and extending in a direction parallel to the torsion axis, and a part of which is cut so as to make a mass of the oscillating plate adjustable,

wherein a region forming the groove portion is taken as at least either one of the front face and the back base in the oscillating plate or the extend portion.

Further, the oscillating body apparatus of the present invention is wherein the groove portion is formed across from one side to the other side of the oscillating plate or the extended portion in a direction orthogonal to the torsion axis.

Further, the optical deflector of the present invention is characterized by including any of the oscillating body apparatuses described above, and an optical deflection element provided in the oscillating plate in the oscillating body apparatus.

Further, the image forming apparatus of the present invention is characterized by including a light source, a photosensitive member, and the optical deflector, deflecting light from the light source by the optical deflector, and allowing at least a part of the light to be incident on the photosensitive member.

Further, the manufacturing method of the oscillating body apparatus of the present invention is a manufacturing method which includes an oscillating plate oscillatably supported around a torsion axis by a support portion for a fixing portion and drives the oscillating plate around the torsion axis by the resonance frequency,

characterized by forming a groove portion in a region of the oscillating plate to adjust the resonance frequency of the oscillating plate, and including a step of adjusting a mass of the oscillating plate by the formation of the groove portion.

Further, the manufacturing method of the oscillating body apparatus of the present invention forms a structure having the frequencies of at least two intrinsic vibration modes around the torsion axis by a first oscillating plate and a second oscillating plate as the oscillating plates when adjusting a mass of the oscillating plate,

wherein the groove portion is formed in at least either one region of the first oscillating plate and the second oscillating plate.

Further, the manufacturing method of the oscillating body apparatus of the present invention forms an extended portion connected to the oscillating plate and extending in a direction parallel to the torsion axis as the oscillating plate when adjusting a mass of the oscillating plate, characterized by performing a first step of adjusting a mass of the oscillating plate by cutting off a part of the extended portion, and a second step of adjusting a mass of the oscillating plate by forming the groove portion at least at either one of the front face and the back base of the oscillating plate or the extended portion, and performing both of the first step and the second step or the second step only.

Further, the manufacturing method of the oscillating body apparatus of the present invention is characterized by detecting the frequency of the intrinsic vibration mode around the torsion axis of the oscillating plate when adjusting the resonance frequency of the oscillating plate, and

based on a difference between the detected frequency and the predetermined resonance frequency, deciding an adjusting amount of the inertia moment of the oscillating plate.

Further, the manufacturing method of the oscillating body apparatus of the present invention is characterized by deciding at least any one of a width of the groove portion, a depth of the grove portion, and the number of groove portions based on the adjusting amount of the inertia moment of the oscillating body.

Further, the manufacturing method of the oscillating body apparatus of the present invention is wherein the grove portion is formed across one side from the other side of the oscillating plate or the extended portion in the direction orthogonal to the torsion axis by irradiation of a laser beam.

According to the present invention, when adjusting the resonance frequency, an oscillating body apparatus and a manufacturing method thereof capable of adjusting a mass of the oscillating plate, an optical deflector using the oscillating body apparatus, and an image forming apparatus can be realized by a simple configuration at a low price in a high precision.

Further features of the present invention will become apparent from the following description of exemplary embodiments with reference to the attached drawings.

### BRIEF DESCRIPTION OF THE DRAWINGS

FIG. 1 is a view illustrating the configuration of an oscillating body apparatus in the embodiment of the present invention.

FIGS. 2A and 2B are views for describing a step of forming a groove portion adjustable in inertia moment in an oscillating plate in the embodiment of the present invention; FIG. 2A is a view illustrating a configuration forming a linear groove portion in the oscillating plate, and FIG. 2B is a sectional view cut along the line B-B of FIG. 2A.

FIG. 3 is a view illustrating the case where a mass of a specific portion of the oscillating plate in a comparison example is removed.

FIG. 4 is a view illustrating an example of the method of forming the groove portion in the oscillating plate in the embodiment of the present invention.

FIG. 5 is a view illustrating the oscillating apparatus and the manufacturing method thereof in a first embodiment of the present invention.

FIG. 6 is a view illustrating the oscillating apparatus and the manufacturing method thereof in a second embodiment of the present invention.

FIG. 7 is a view for illustrating a locus of a sinusoidal wave vibration and a rough saw tooth wave vibration in the second embodiment of the present invention.

FIG. 8 is a view illustrating an image forming apparatus in the third embodiment of the present invention.

FIG. 9 is a view illustrating a planar type galvano mirror in Japanese Patent Application Laid-Open No. 2002-040355 which is a conventional example.

### BEST MODES FOR CARRYING OUT THE INVENTION

Preferred embodiments of the present invention will now be described in detail in accordance with the accompanying drawings.

Next, an oscillating body apparatus and a manufacturing method thereof in the embodiments of the present invention will be described.

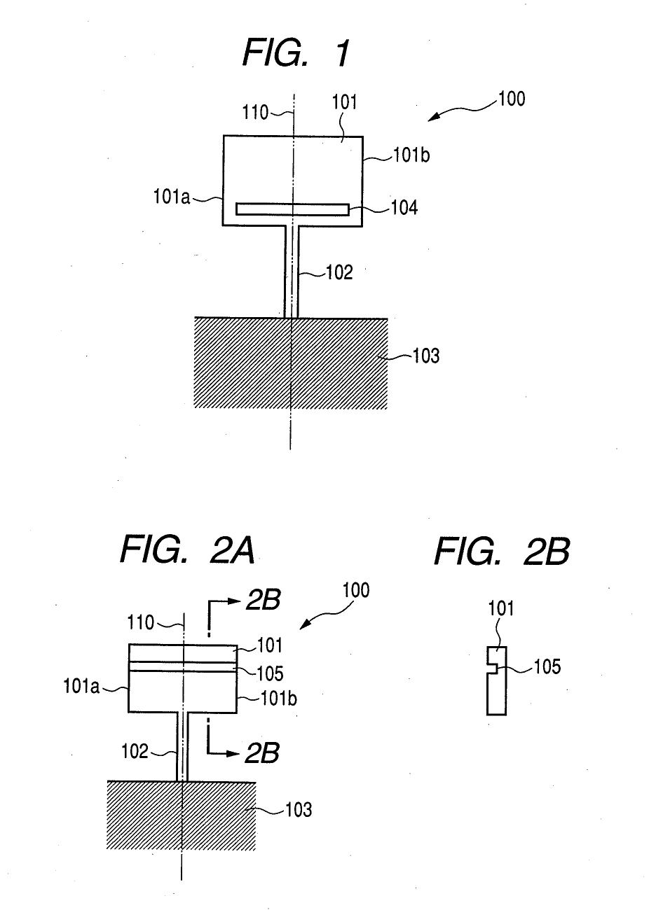

In FIG. 1 is shown a view illustrating a configuration of an oscillating body apparatus in the present embodiment.

In FIG. 1, reference numeral 100 denotes an oscillating body apparatus, numeral 101 an oscillating plate, numeral 102 an elastic support portion, numeral 103 a fixing portion, and numeral 104 a permanent magnet.

In the oscillating body apparatus of the present embodiment, the oscillating plate 101 is supported to the fixing portion 103 by the elastic support portion 102.

The oscillating plate 101 has sides 101a and 101b which are in parallel with a torsion axis 110.

The elastic support portion 102 elastically and torsion-oscillatably supports the oscillating plate 101 with the axis 110 as a center.

The oscillating body apparatus 100 has an intrinsic vibration mode of a torsion oscillation around the torsion axis 110.

Its frequency f is represented by the following formula.

f=1/(2·π)·√(k/I) (Formula 1)

wherein k indicates a torsion spring constant around the torsion axis 110 of the elastic support portion 102 and I indicates an inertia moment around the torsion axis 110 of the oscillating plate 101.

Further, the oscillating plate 101 is provided with the permanent magnet 104.

The permanent magnet 104 is magnetized in the longitudinal direction of the Figure. An alternating-current magnetic field is applied by an unillustrated electro magnetic coil and torque can be generated.

By setting the frequency of the alternating-current magnetic filed close to a frequency f of the intrinsic vibration mode, an oscillation utilizing the resonance phenomenon can be performed.

When manufacturing the oscillating body apparatus as described above, by adjusting the inertia moment by the following method, the frequency of the intrinsic vibration mode can be adjusted in a high precision.

First, the oscillating body apparatus 100 is driven, and the frequency f of the intrinsic vibration mode is detected.

As a method of detecting the frequency f, for example, the frequency of alternating-current magnetic field applied to the electro magnetic coil is swept, and by drive waveform detection unit, an amplitude of the vibration in the torsion direction of the oscillating body apparatus 100 is detected, and the frequency of the alternating-current magnetic field in which the amplitude becomes the maximum is taken as the frequency f of the intrinsic vibration mode and the like.

From a difference between the frequency of the intrinsic vibration mode measured by such measurement unit and an adjustment target value, the necessary inertia moment adjustment amount is calculated by using a relationship of the formula (1).

Based on the adjustment amount of the inertia moment of the oscillating plate calculated as described above, at least either one of the width of the groove portion, the depth of the groove portion, and the number of the groove portions is decided, and the groove portion whose inertia moment becomes adjustable as follows is formed in the region of the oscillating plate.

In FIGS. 2A and 2B are shown views describing a step of forming the groove portion whose inertia moment becomes adjustable in the oscillating plate.

FIG. 2A is a view illustrating the configuration in which a linear groove portion is formed in the oscillating plate, and FIG. 2B is a sectional view cut along the line 2B-2B of FIG. 2A.

In the present embodiment, the groove portion is formed across one side to another side of the oscillating plate in the direction orthogonal to the torsion axis.

Specifically, as illustrated in FIG. 2, from a side 101a to a side 101b in parallel with the torsion axis 110 of the oscillating plate 101, a linear groove portion 105 is formed by irradiation with a processing laser beam.

Particularly, when the oscillating body apparatus 100 is manufactured by a semiconductor manufacturing process, its shape can be fabricated extremely highly precise, for example, ±1 μm or less, and therefore, by continuously performing the process from the side 101a to the side 101b, highly precise adjustment of the inertia moment can be achieved.

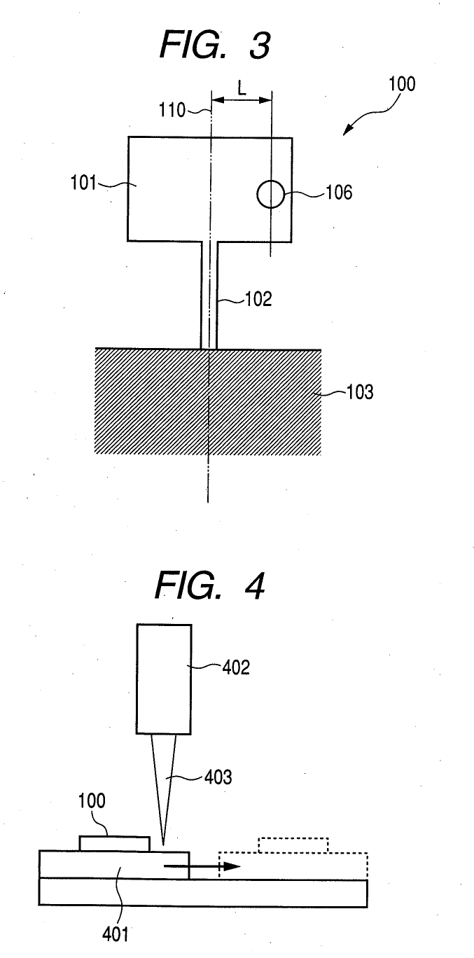

As a comparison example, a description will be made on the case where a mass of a specific portion 106 of the oscillating plate is removed as illustrated in FIG. 3.

An adjustment amount It of the inertia moment around the torsion axis 110 of the oscillating plate 101 is represented as follows.

It=m·L² (Formula 2)

wherein m is the removed amount, and L is a distance between the torsion axis 110 and a center of gravity of the removed portion.

As shown in the Formula (2), since the adjustment amount It of the inertia moment is proportional to squares of the distance L, when an attempt is made to adjust the inertia moment in a high precision, a processing point is required to be adjusted extremely highly precise.

That is, a precision of the deflector for deflecting a processing laser beam and a stage precision for moving the oscillating body apparatus must be placed under strict control, and an expensive cost of the processing apparatus and a lowering of the processing speed cannot be avoided.

Next, an example of the method of forming the groove portion in the oscillating plate 101 in the present embodiment will be described.

In FIG. 4 is shown a view for describing the method.

The oscillating body apparatus 100 is mounted on a stage 401. A laser light source 402 is installed so that a processing laser beam 403 focuses the oscillating plate 101, and the oscillating plate 101 moves to an arrow direction by the stage 401, so that the groove portion can be continuously formed from a side 101a to a side 101b of the oscillating plate 101.

The inertia moment by the processing has the side 101a and the side 101b in parallel with the torsion axis 110 of the oscillating plate 101.

Hence, the inertia moment is not affected by the positional error of the stage in a normal direction to a paper face, and moreover, is processed from the side to the side of the oscillating plate 101, and therefore, is not affected by the positional error of the travelling direction stage of the stage 401.

As a result, the adjustment accuracy of the inertia moment has sensitivity only for the shape accuracy of the oscillating plate 101, and does not depend on the positional accuracy of the stage 401.

Therefore, the stage of a low accuracy and a high speed drive can be used, and a low price of the apparatus and improvement of a processing speed can be achieved. Although the movement of the processing position has been performed by the stage, even when the processing laser beam 403 is scanned by the optical deflector and the like, the same effect can be obtained.

As described above, according to the present embodiment, by the process not depending on a positioning accuracy of the processing apparatus, the groove portion in which the inertia moment is adjustable is formed in the oscillating plate, so that the frequency of the intrinsic vibration mode can be adjusted in a high precision.

Further, the reflection surface which is an optical deflection element is configured to be arranged on the oscillating plate of such oscillating body apparatus, so that this oscillating body apparatus can be used as an optical deflector.

Further, an image forming apparatus including such an optical deflector, the light source, and the photosensitive member, and deflecting a light from the light source by the optical deflector, and allowing at least a part of the light to be incident on the photosensitive member can be configured.

### EMBODIMENTS

Embodiments of the present invention will be described below.

### First Embodiment

In a first embodiment, a configuration example of the oscillating body apparatus and the manufacturing method thereof applied with the configuration of the present invention will be described.

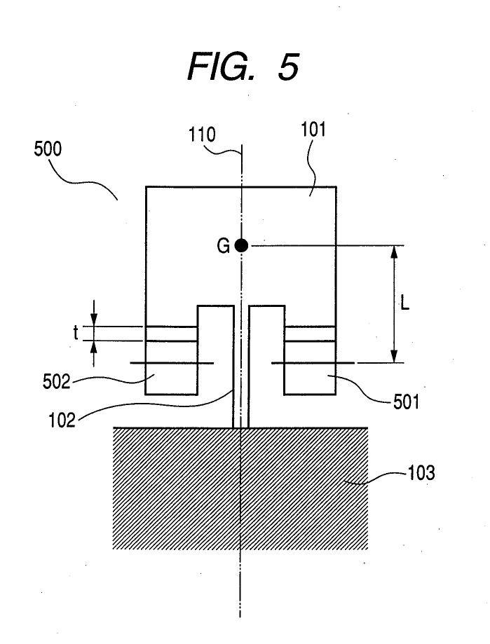

In FIG. 5 is shown a view illustrating the oscillating body apparatus and the manufacturing method thereof in the present embodiment.

FIG. 5 has the same reference numerals attached for the same configuration as the embodiment shown in FIG. 1, and therefore, a description on the common parts will be omitted.

In FIG. 5, reference numeral 500 denotes an oscillating body apparatus and numerals 501 and 502 an extended portion.

In an oscillating body device 500 of the present embodiment, an oscillating plate 101 is 300 μm in thickness, and a length in the direction of a torsion axis 110 is 1 mm, and a width is 3 mm.

The oscillating plate 101 includes extended portions 501 and 502.

These extended portions 501 and 502, as illustrated in FIG. 5, include extended portions which are connected with the oscillating plate 101 at symmetrical positions sandwiching a torsion axis 110, and extend in a direction parallel to the torsion axis, and a part of which is cut so as to make a mass of the oscillating plate adjustable.

The groove portion is configured to be formable on at least either one of the surface or the back face of the extended portion.

The oscillating plate 101, the elastic support portion 102, and the fixing portion 103 are formed by etching single crystal silicon by dry etching.

The oscillating body apparatus 500 includes an intrinsic vibration mode of a torsion vibration around a torsion axis 110.

Its frequency f is represented by the (Formula 1) described in the above described embodiment.

Since a spring constant K and an inertia moment I change by manufacture variation and environment variation, an error arises between the frequency f of the fabricated oscillating body apparatus and the frequency of the predetermined target.

Hence, when manufacturing the oscillating body apparatus, the inertia moment is adjusted, thereby enabling the frequency of the intrinsic vibration mode to be adjusted in a high precision.

First, the frequency of the intrinsic vibration mode is measured, and from a difference between the measured frequency and the adjustment target value, the necessary inertia moment adjustment amount is calculated by using the relationship of the (Formula 1).

According to the calculated inertia moment adjustment amount, the frequency of the oscillating plate is adjusted by the following two processes.

The two processes include a first process of cutting off the extended portion and a second process of continuously forming a linear groove portion from a side to a side of the extended portion.

In the first process, a position to cut the extended portion according to the inertia moment adjustment amount is controlled.

That is, when the adjustment amount is large, the cutting distance L in the Figure is made short, and when the adjustment amount is small, the cutting distance L in the Figure is made long.

In the present embodiment, though the cutting distance takes a center of gravity G of the oscillating plate as a reference, an end portion, an alignment mark, and the like may be taken as a reference.

Preferably, both of the extended portions arranged symmetrical to the torsion axis 110 are desirable to be cut, but either one of the extended portions may be cut.

By cutting off the extended portion, as compared with the second process to be described below, a large amount of inertia moment can be adjusted.

In the second process, according to the inertia moment adjustment amount, a width t of the linear groove portion continuously formed on a side from a side of the extended portion is controlled.

That is, when the adjustment amount is large, the groove width t in the Figure is made wide, and when the adjustment amount is small, the groove width t in the Figure is made narrow.

In the present embodiment, though the groove width is adjusted, the groove depth or the number of grooves may be adjusted.

By forming the groove portion in a protruded shape formed precisely by dry etching, the inertia moment can be adjusted in a high precision.

By performing the first process and the second process or performing the second process only, the frequency of the oscillating body apparatus 500 can be precisely and promptly adjusted.

### Second Embodiment

In a second embodiment, an oscillating body apparatus and the manufacturing method thereof of an embodiment different from the first embodiment will be described.

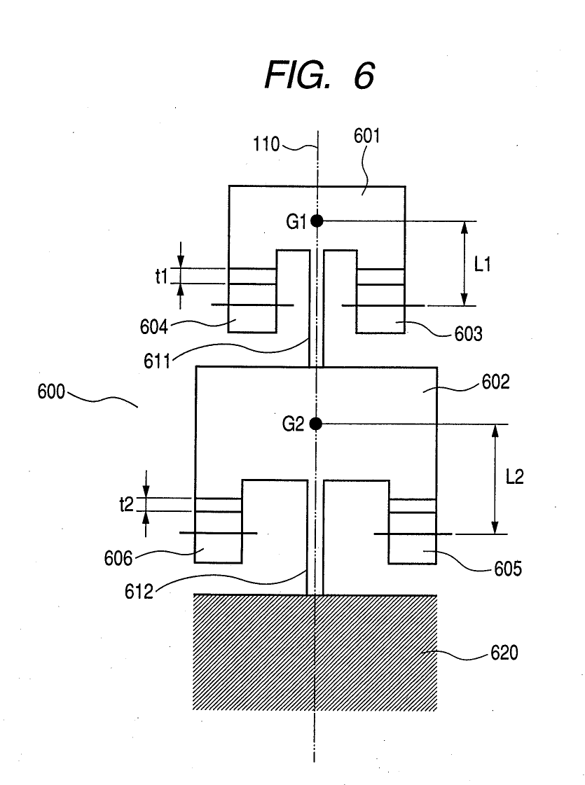

In FIG. 6 is shown a view for describing an oscillating body apparatus and a manufacturing method thereof in the present embodiment.

In FIG. 6, reference numeral 601 denotes a first oscillating plate, numeral 602 a second oscillating plate, numeral 611 a first elastic support portion, and numeral 612 a second elastic support portion.

An oscillating body apparatus 600 of the present embodiment has a structure in which an oscillating plate includes the frequencies of at least two intrinsic vibration modes around the torsion axis by the first oscillating plate and the second oscillating plate.

Specifically, the oscillating body apparatus comprises the first oscillating plate 601, the second oscillating plate 602, the first elastic support portion 611, the second elastic support portion 612, and a fixing portion 620.

Here, the first oscillating plate 601 is 300 μm in thickness, a length in the direction to a torsion axis 110 is 1 mm, and a width is 3 mm.

Further, the second oscillating plate 602 is 300 μm in thickness, a length in the direction to a torsion axis 110 is 2 mm, and a width is 6 mm.

The oscillating plate includes extended portions 603, 604, 605, and 606, and the extended portions are connected to the oscillating plates 601 and 602 at the symmetrical positions as illustrated by sandwiching the torsion axis 110.

All the extended portions are formed so as to extend in the direction parallel to the torsion axis 110.

The first oscillating plate 601 and the second oscillating plate 602 are torsion-oscillatably connected by the first elastic support portion 611, and the second oscillating plate 602 is torsion-oscillatably connected to a fixing portion 620 by the second elastic support portion 612.

The oscillating plate, the elastic support portion, and the fixing portion are formed by etching single crystal silicon by dry etching.

The oscillating body apparatus 600 has the frequencies f1 and f2 of two intrinsic modes around the torsion axis 110.

The oscillating body apparatus can realize a torsion vibration synthesizing two sinusoidal waves by applying a driving force including the two intrinsic modes.

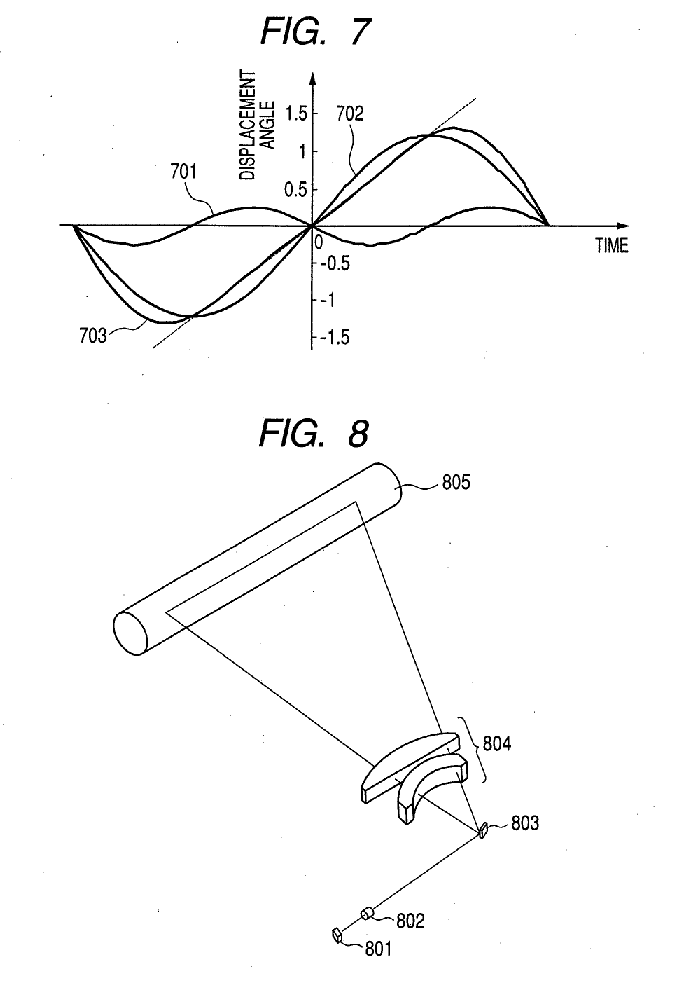

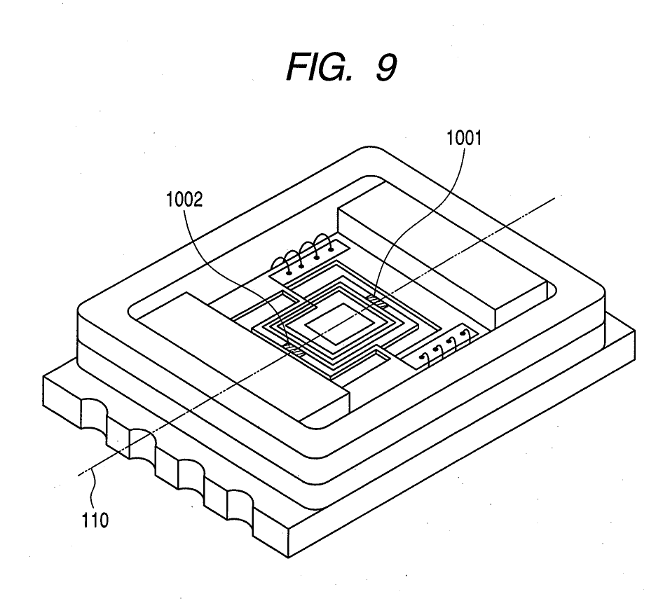

Particularly, when f1 and f2 are in a relationship of being twice as high, by adjusting the amplitudes of two sinusoidal vibrations 701 and 702, a coarse saw tooth wave vibration 703 as illustrated in FIG. 7 can be realized.

The coarse saw tooth wave vibration 703, as compared with the sinusoidal wave, can widely set up a region in which the angular speed is substantially constant, and can enlarge the available region relative to the whole deflection scanning.

In the meantime, to obtain the predetermined synthetic waveform as described above, it is necessary to adjust the frequencies f1 and f2 of two intrinsic modes of the oscillating body apparatus in a high precision.

In general, the frequencies f1 and f2 of the two intrinsic vibration modes of a vibration system including two pieces each of the oscillating plate and the elastic support portion are represented by the following formula (3).

$$f 1 = \sqrt{\frac{I 2 k 1 + I 1 k 2 + I 2 k 2 - \sqrt{\begin{matrix}- 4 I 1 I 2 k 1 k 2 + \\ {( \begin{matrix}I 1 k 2 + I 2 \\ ( k 1 + k 2 )\end{matrix} )}^{2}\end{matrix}}}{8 I 1 I 2 {π}^{2} }} \\ f 2 = \sqrt{\frac{I 2 k 1 + I 1 k 2 + I 2 k 2 + \sqrt{\begin{matrix}- 4 I 1 I 2 k 1 k 2 + \\ {( \begin{matrix}I 1 k 2 + I 2 \\ ( k 1 + k 2 )\end{matrix} )}^{2}\end{matrix}}}{8 I 1 I 2 {π}^{2}}} \qquad ( Formula 3 )$$

Wherein k1 and k2 indicate a torsion spring constant around the torsion axis 110 of the first elastic support portion 611 and the second elastic support portion 612, numerals I1 and I2 indicate the inertia moment around the torsion axis 110 of the first oscillating plate 601 and the second oscillating plate 602.

Since the spring constant K and the inertial moment I change by manufacture variation and environment variation, an error arises between a frequency f of the fabricated oscillating body apparatus and a frequency of the predetermined target.

Hence, the inertial moment is adjusted by the following method when manufacturing the oscillating body apparatus, so that the frequency of the intrinsic vibration mode can be adjusted in a high precision.

First, the frequency of the intrinsic vibration mode is measured, and from a difference between the measured frequency and the adjustment target value, the necessary inertia moment adjustment amounts of each of the first oscillating plate 601 and the second oscillating plate 602 is calculated by using the relationship of the (Formula 3).

According to the calculated inertia moment adjustment amount, each of the inertia moments of the first oscillating plate 601 and the second oscillating plate 602 is adjusted by the following two processes, thereby to adjust f1 and f2 of the oscillating body apparatus 600.

The two processes include a first process of cutting off the extended portion and a second process of continuously forming a linear groove portion from a side to a side of the extended portion.

In the first process, a position to cut the extended portion according to the inertia moment adjustment amount is controlled.

That is, when the adjustment amount of the first oscillating plate is large, the cutting distance L1 in the Figure is made short, and when the adjustment amount is small, the cutting distance L1 in the Figure is made long; and, when the adjustment amount of the second oscillating plate is large, the cutting distance L2 in the Figure is made short, and when the adjustment amount is small, the cutting distance L2 in the Figure is made long.

In the present embodiment, though a center of gravity of the oscillating plate is taken as a reference, an end portion and an alignment mark may be taken as a reference.

Preferably, both of the extended portions arranged symmetrical to the torsion axis 110 are desirable to be cut, but either one of the extended portions may be cut.

By cutting off the extended portion, as compared with the second process to be described below, a large amount of inertia moment can be adjusted.

In the second process, according to the inertia moment adjustment amount, a width t of the linear groove portion continuously formed on a side from the extended portion is controlled.

That is, when the adjustment amount is large, the groove width t in the Figure is made wide, and when the adjustment amount is small, the groove width t in the Figure is made narrow.

In the present embodiment, though the groove width is adjusted, the groove depth or the number of grooves may be adjusted.

By forming the groove in a protruded shape formed precisely by dry etching, the inertia moment can be adjusted in a high precision.

By performing both of the first process and the second process or performing the second process only, the frequency of the oscillating body apparatus 600 can be precisely and promptly adjusted.

### Third Embodiment

In a third embodiment, a configuration example of an image forming apparatus using an optical deflector comprised by applying an oscillating body apparatus of the present invention will be described.

In FIG. 8 is illustrated a schematic oblique view for describing the configuration example of the image forming apparatus in the present embodiment.

In the image forming apparatus of the present embodiment illustrated in FIG. 8, reference numeral 803 denotes an optical deflector comprised by applying the oscillating body apparatus of the present invention. In the present embodiment, an incident light is one-dimensionally scanned.

Numeral 801 denotes a laser light source, numeral 802 a lens or a group of lenses, numeral 804 a write lens or a lens group, and numeral 805 a photosensitive member having a drum shape.

The laser light emitted from the laser light source 801 receives the predetermined intensity modulation related to a timing of deflection scanning of the light.

This intensity modulated light passes through a lens or a lens group 802, and is one-dimensionally scanned by an optical scanning system (optical deflector) 803.

This scanned laser light forms an image on a photosensitive member 805 by a write lens or a lens group 804.

The photosensitive member 805 rotated around an axis of rotation in the direction vertical to the scanning direction is uniformly charged by an unillustrated charger, and by scanning a light on this body, an electrostatic latent image is formed on the scanned portion.

Next, by an unillustrated developing device, a toner image is formed on the image portion of the electrostatic latent image, and by transferring and fixing this toner image, for example, on an unillustrated sheet, an image is formed on the sheet.

By the oscillating body apparatus of the present invention, an oscillating body apparatus suitably adjusted to the predetermined frequency can be used.

Consequently, the apparatus can be driven in a state of a high amplitude amplification factor, and this makes the apparatus small, and reduces the power consumption.

Further, when the oscillating body apparatus of the second embodiment is used, the angular velocity of the deflection scanning of the light can be made approximately the constant angular velocity within the specification of the photosensitive member 805.

Further, by using the optical deflector comprised by the oscillating body apparatus of the present invention, variance of the scanning position is reduced, thereby achieving an image forming apparatus capable of generating a clear image.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2007-223640, filed Aug. 30, 2007, and Japanese Patent Application No. 2008-069761, filed Mar. 18, 2008, which are hereby incorporated by reference herein in their entirety.

1. An oscillating body apparatus comprising an oscillating plate oscillatably supported around a torsion axis by a support portion for a fixing portion and driving the oscillating plate around the torsion axis by a resonance frequency,
the oscillating plate having a region forming a groove portion for adjusting a mass of the oscillating plate, and, the resonance frequency being configured to be adjustable by the formation of the groove portion in the region.

2. The oscillating body apparatus according to claim 1, wherein the oscillating plate includes a structure having the frequencies of at least two intrinsic vibration modes around the torsion axis by a first oscillating plate and a second oscillating plate, and
the groove portion is configured to be formable in the region that forms the groove portion in at least one of the first oscillating plate and the second oscillating plate.

3. The oscillating body apparatus according to claim 1, wherein the oscillating plate is accompanied by an extended portion connected to the oscillating plate and extending in a direction parallel to the torsion axis a part of which portion is cuttable so as to make a mass of the oscillating plate adjustable, and
the region forming the groove portion is taken as at least one of the front face and the back base in the oscillating plate or the extend portion.

4. The oscillating body apparatus according to claim 3, wherein the groove portion is formed across from one side to the other side of the oscillating plate or the extended portion in a direction orthogonal to the torsion axis.

5. An optical deflector, comprising:
an oscillating body apparatus according to claim 1; and
an optical deflection element provided in the oscillating plate in the oscillating body apparatus.

6. An image forming apparatus, comprising a light source, a photosensitive member, and an optical deflector according to claim 5,
wherein light from the light source being deflected by the optical deflector, and at least a part of the light being allowed to be incident on the photosensitive member.

7. A manufacturing method for manufacturing an oscillating body apparatus which is comprised of an oscillating plate oscillatably supported around a torsion axis by a support portion for a fixing portion and driving the oscillating plate around the torsion axis by a resonance frequency, comprising the steps of:
forming a groove portion in a region of the oscillating plate to adjust the resonance frequency of the oscillating plate to adjust a mass of the oscillating plate.

8. The manufacturing method of the oscillating body apparatus according to claim 7, wherein when adjusting the mass of the oscillating plate, a structure having frequencies of at least two intrinsic vibration modes around the torsion axis is formed with a first oscillating plate and a second oscillating plate as the oscillating plates, and
the groove portion is formed in at least one region of the first oscillating plate and the second oscillating plate.

9. The manufacturing method of the oscillating body apparatus according to claim 7, wherein when adjusting the mass of the oscillating plate, both the following first and second steps are performed or only second step is performed, the first step of forming an extended portion connected to the oscillating plate and extending in a direction parallel to the torsion axis as the oscillating plate, and a part of the extended portion is cut to adjust the mass of the oscillating plate, and the second step of forming the groove portion at least one of the front face and the back base of the oscillating plate or the extended portion to adjust the mass of the oscillating plate.

10. The manufacturing method of the oscillating body apparatus according to claim 7, wherein the frequency of the intrinsic vibration mode around the torsion axis of the oscillating plate is detected when adjusting the resonance frequency of the oscillating plate, to decide an adjusting amount of the inertia moment of the oscillating plate based on a difference between the detected frequency and the predetermined resonance frequency.

11. The manufacturing method of the oscillating body apparatus according to claim 10, wherein at least one of the width, the depth and the number of the groove portions is decided based on the adjusting amount of the inertia moment of the oscillating plate.

12. The manufacturing method of the oscillating body apparatus according to claim 7, wherein the grove portion is formed across from one side to the other side of the oscillating plate or the extended portion in the direction orthogonal to the torsion axis by irradiation with a laser beam.
